(19) United States
(12) Patent Application Publication
(10) Pub. No.: US 2006/0138559 A1
(43) Pub. Date: Jun. 29, 2006

(54) Flash memories having at least one resistance pattern on gate pattern and methods of fabricating the same

(76) Inventors: Dong-Jun Lee, Gyeonggi-do (KR); Keon-Soo Kim, Gyeonggi-do (KR); Hyun-Chul Back, Gyeonggi-do (KR); Seong-Soon Cho, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/317,595

(22) Filed: Dec. 23, 2005

(30) Foreign Application Priority Data
Dec. 24, 2004 (KR) 2004-112334

(51) Int. Cl. H01L 29/00; H01L 21/8234

(52) U.S. Cl. 257/379; 257/536; 438/382; 438/238

(57) ABSTRACT

Flash memories and methods of manufacturing the same provide at least one resistance pattern on a gate pattern, and are capable of increasing a process margin in the semiconductor fabrication process. Gate patterns and bit line patterns are sequentially formed in a cell array region and a peripheral circuit region of a semiconductor substrate. A bit line interlayer insulating layer is disposed to cover the bit line patterns. At least one resistance pattern is disposed on the bit line interlayer insulating layer in the cell array region of the semiconductor substrate. A planarized interlayer insulating layer is formed on the bit line interlayer insulating layer to cover the resistance pattern. Interconnection lines such as metal interconnection lines are formed on the planarized interlayer insulating layer in the cell array region and the peripheral circuit region of the semiconductor substrate.

### CROSS-REFERENCE TO RELATED APPLICATIONS

This application claims priority from Korean Patent Application No. 10-2004-0112334, which was filed on 24 Dec. 2004. The related application identified above is incorporated by reference in its entirety.

### BACKGROUND

1. Technical Field

This disclosure relates to semiconductor devices having discrete elements and methods of fabricating the same, and more particularly, to flash memories having at least one resistance pattern on a gate pattern and methods of fabricating the same.

2. Description of the Related Art

Generally, a flash memory uses a resistance pattern in order to process user data within a predetermined time. The resistance pattern is used in a time delay chain using resistance and capacitance in the logic structure of a flash memory. The resistance pattern may be formed on an isolation layer of a semiconductor substrate in order to freely change a resistance according to the user's demands for a flash memory. The isolation layer is disposed in the semiconductor substrate to isolate active regions of the substrate. The user's demands may vary depending on, e.g., a logic structure, a design rule, or a voltage in use.

However, the resistance pattern has a small allowance area to be disposed on the isolation layer during the formation of gate patterns on the active regions in the semiconductor fabrication. This is because the resistance pattern is formed of one material layer or more to form a gate pattern. This means that the resistance pattern is formed on the semiconductor substrate concurrently with the gate pattern.

U.S. Pat. No. 5,489,547 to Erdeljac, et al. (“Erdeljac”) discloses a method of fabricating a semiconductor device having a polysilicon resistor. According to Erdeljac, the method includes forming two resistors on a field oxide region of a semiconductor substrate. One of the resistors has a relatively low sheet resistance and the other one has a relatively high sheet resistance.

The method disclosed by Erdeljac can provide good structural characteristics for a semiconductor device having polysilicon resistors only when a thickness of the oxide layer in the field oxide region is controlled properly. This is because a parasitic capacitance may be generated between resistors and a semiconductor substrate by a user voltage during the drive period of a semiconductor device if the oxide layer is too thin.

Embodiments of the invention address these and other disadvantages of the related art.

### SUMMARY

According to some embodiments, a flash memory has at least one resistance pattern on a gate pattern that is suitable for minimizing the influence of semiconductor fabrication processes. According to some embodiments, a method of fabricating flash memories having at least one resistance pattern on a gate pattern may achieve good structural characteristics by minimizing the influence of semiconductor fabrication processes.

### BRIEF DESCRIPTION OF THE DRAWINGS

The above and other features and advantages of the invention will become more apparent to those of skill in the art by describing in detail preferred embodiments thereof with reference to the attached drawings.

FIG. 1 is a plan diagram illustrating a flash memory according to some embodiments of the invention.

FIG. 2 is a sectional diagram, taken along line I-I′ of FIG. 1, which further illustrates the flash memory of FIG. 1.

FIGS. 3 to 13 are sectional diagrams, taken along line I-I′ of FIG. 1, which illustrate a method of fabricating the flash memory of FIG. 1 according to some embodiments of the invention.

### DETAILED DESCRIPTION

The principles of the invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

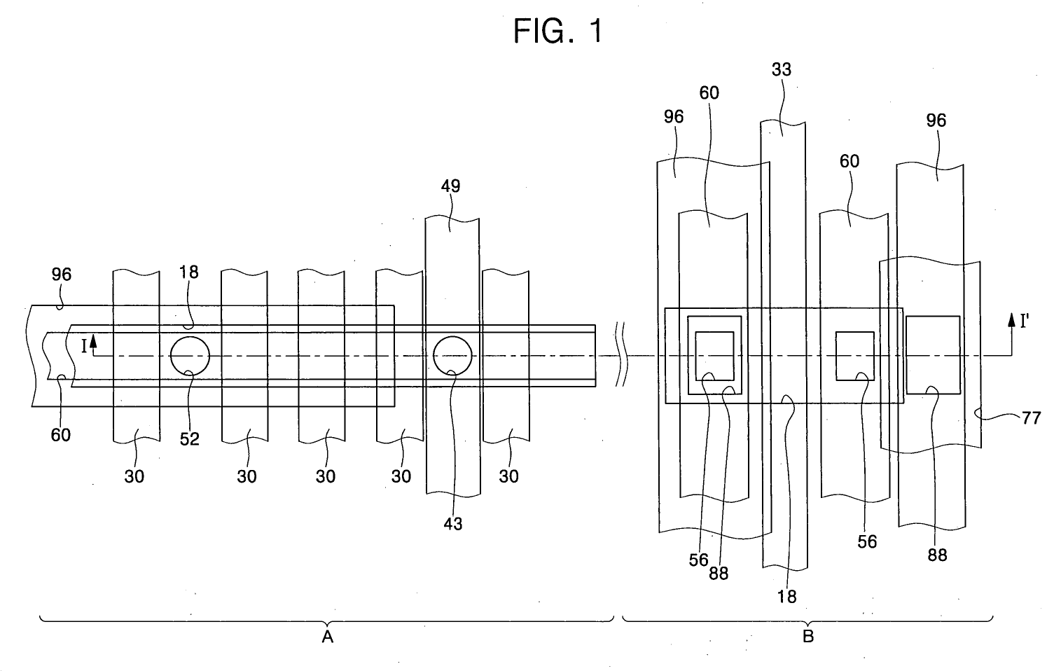

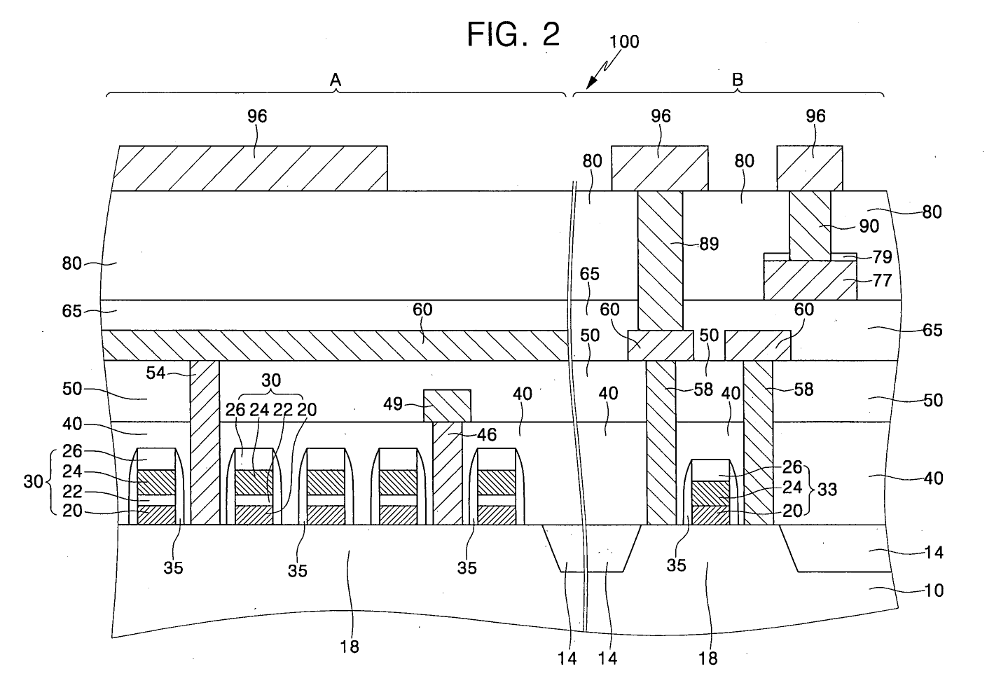

FIG. 1 is a plan diagram illustrating a flash memory according to some embodiments of the invention. FIG. 2 is a sectional diagram, taken along line I-I′ of FIG. 1, which further illustrates the flash memory of FIG. 1.

Referring to FIGS. 1 and 2, a semiconductor substrate 10 having a cell array region A and a peripheral circuit region B is prepared. Gate patterns 30, 33 are disposed on the semiconductor substrate 10 of the cell array region A and the peripheral circuit region B. In the cell array region A, the gate patterns 30 are disposed on the semiconductor substrate 10 and are parallel to each other. The gate pattern 30 includes a floating gate 20, a dielectric layer 22, a control gate 24, and a gate capping layer pattern 26, which are sequentially stacked.

In the peripheral circuit region B, the gate pattern 33 includes a floating gate 20, a control gate 24, and a gate capping layer pattern 26, which are sequentially stacked. The control gate 24 and the floating gate 20 are preferably composed of conductive polysilicon. The dielectric layer 22 includes silicon oxide (SiO₂), silicon nitride (Si₃N₄), and silicon oxide, which are sequentially stacked. Gate spacers 35 are disposed on the sidewalls of each of the gate patterns 30. The gate spacers 35 are preferably composed of silicon nitride or silicon oxide.

Bit line patterns 60 are disposed on the gate patterns 30, 33. The bit line patterns 60 are disposed in the cell array region A and the peripheral circuit region B, and are preferably composed of tungsten (W).

As shown in FIG. 2, a resistance pattern 77, preferably composed of conductive polysilicon, is disposed over a bit line pattern 60 in the peripheral circuit region B. In some embodiments of the invention, a resistance pattern 77 may be disposed in the cell array region A.

Preferably, when the resistance pattern 77 is disposed in the cell array region A, the resistance pattern is disposed in parallel with the longitudinal direction of the bit line pattern 60, perpendicular to the gate patterns 30. However, a resistance pattern 77 may also be disposed perpendicular to the longitudinal direction of the bit line patterns 60, in regions between the gate patterns 30.

Interconnection lines such as metal interconnection lines 96 are disposed in the cell array region A and the peripheral circuit region B, and are preferably composed of aluminum (Al). In the peripheral circuit region B, the metal interconnection lines 96 are disposed over the resistance pattern 77. In the cell array region A, the metal interconnection lines 96 and the bit line patterns 60 are preferably disposed to run lengthwise in the same direction. When the resistance pattern 77 is disposed in the cell array region A, the metal interconnection lines 96 in the cell array region A may be electrically connected to the resistance pattern 77.

As illustrated in FIG. 1, in the peripheral circuit region B, the resistance pattern 77 is preferably disposed in parallel with the longitudinal direction of the bit line patterns 60 and the metal interconnection lines 96. However, in alternative embodiments the resistance pattern 77 may be disposed perpendicular to the longitudinal direction of the bit line patterns 60 and the metal interconnection lines 96. At least one of the metal interconnection lines 96 in the peripheral circuit region B is electrically connected to the resistance pattern 77.

A gate interlayer insulating layer 40 and a buried interlayer insulating layer 50 are sequentially stacked on the gate patterns 30, 33. In the cell array region A, source and drain landing pads 46, 54 are disposed between the gate patterns 30. The drain landing pad 54 penetrates the gate interlayer insulating layer 40 and the buried interlayer insulating layer 50 so as to contact the bit line pattern 60. The source landing pad 46 penetrates the gate interlayer insulating layer 40 so as to contact the source line 49. The source line 49 and the source landing pads 46, 54 are preferably composed of tungsten. The drain landing pad 54 is preferably composed of conductive polysilicon. In the peripheral circuit region B, source and drain plugs 58 may be disposed to either side of the gate pattern 33. The source and drain plugs 58 penetrate the gate interlayer insulating layer 40 and the buried interlayer insulating layer 50 so as to be connected to the bit line patterns 60.

A bit line interlayer insulating layer 65 and a planarized interlayer insulating layer 80 are sequentially stacked to cover the bit line patterns 60. The bit line interlayer insulating layer 65 is disposed between the resistance pattern 77 and the buried interlayer insulating layer 50. The planarized interlayer insulating layer 80 is disposed on the bit line interlayer insulating layer 65 to cover the resistance pattern 77.

As illustrated in FIG. 2, when the resistance pattern 77 is disposed in the peripheral circuit region B, a bit line landing pad 89 is disposed in the bit line interlayer insulating layer 65 and the planarized insulating layer 80. A connection landing pad 90 is disposed in the planarized interlayer insulating layer 80. The connection landing pad 90 is disposed between the resistance pattern 77 and one of the metal interconnection lines 96, while the bit line landing pad 89 is disposed between a bit line pattern 60 and another one of the metal interconnection lines 96. A reflection layer pattern 79 may be disposed to surround the lower portion of the connection landing pad 90.

Similar to the illustrated embodiments, when the resistance pattern 77 is disposed in the cell array region A, the connection landing pad 90 may be disposed in the planarized interlayer insulating layer 80. In this case, the connection landing pad 90 is also disposed between the resistance pattern 77 and the metal interconnection line 96.

An isolation layer 14 is disposed in the cell array region A and the peripheral circuit region B of the semiconductor substrate 10. The isolation layer 14 is preferably disposed to isolate active regions 18. Preferably, the resistance pattern 77 is aligned with the isolation layer 14 such that a vertical line passing through the resistance pattern, preferably the center of the resistance pattern, also passes through the isolation layer. In some embodiments, the resistance pattern 77 may be disposed to cross over the active regions 18. Therefore, according to embodiments of the invention, the resistance pattern 77 is disposed on the gate patterns 30, 33 via the fabrication procedure of semiconductor devices to provide a flash memory 100.

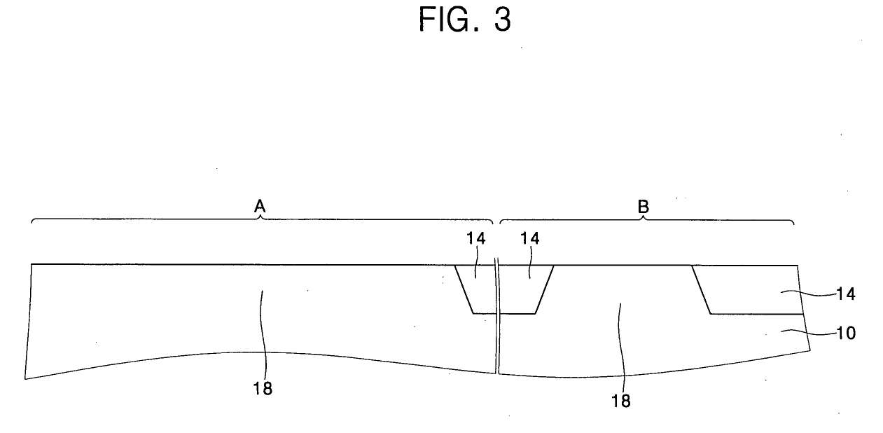

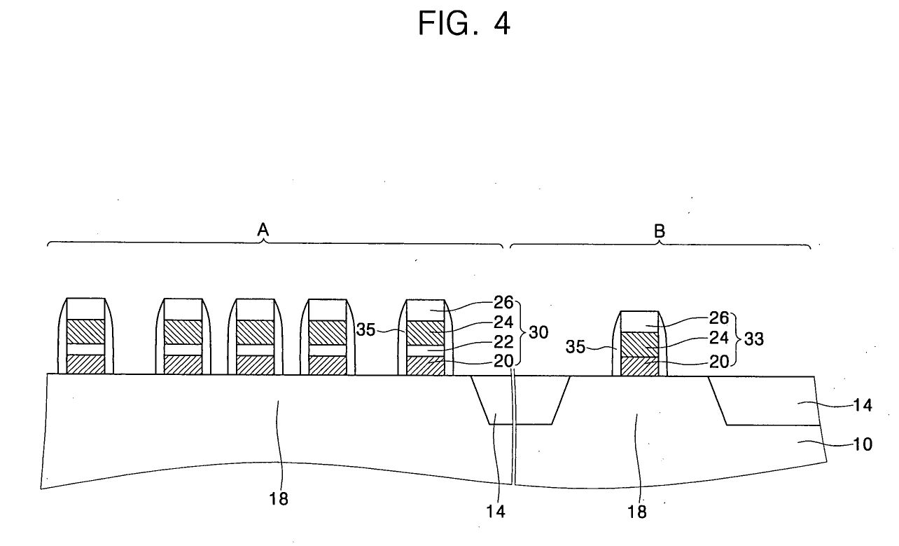

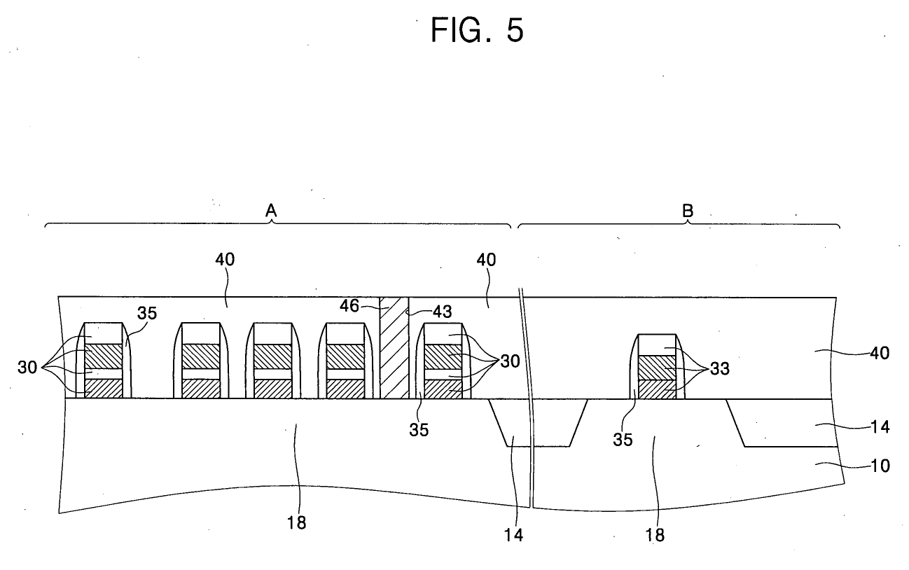

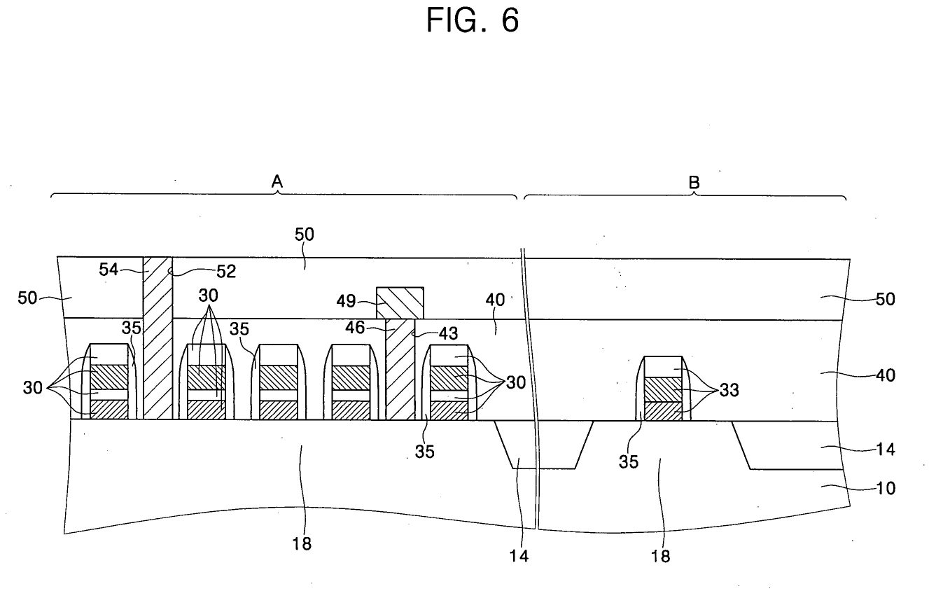

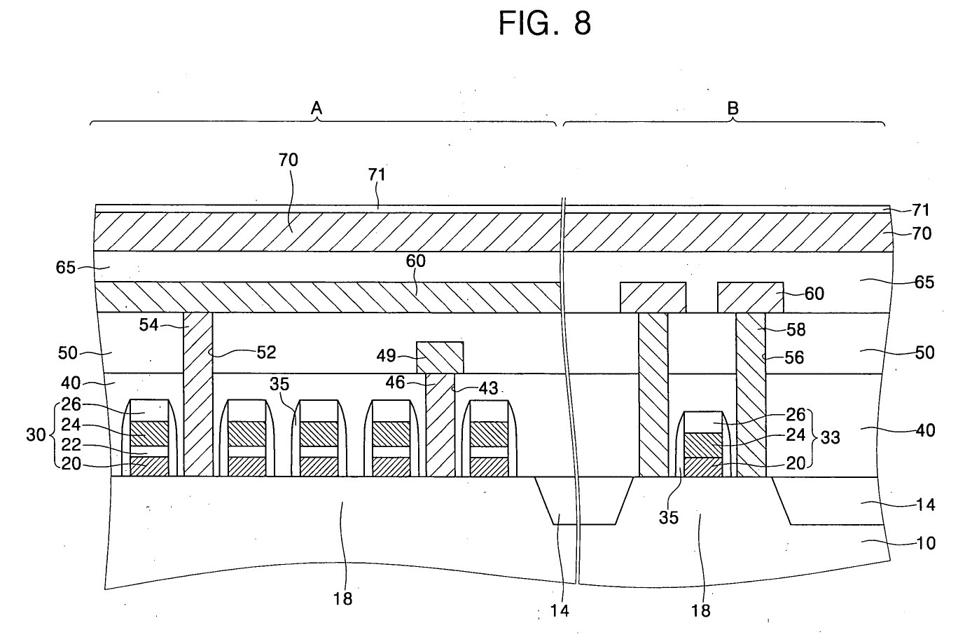

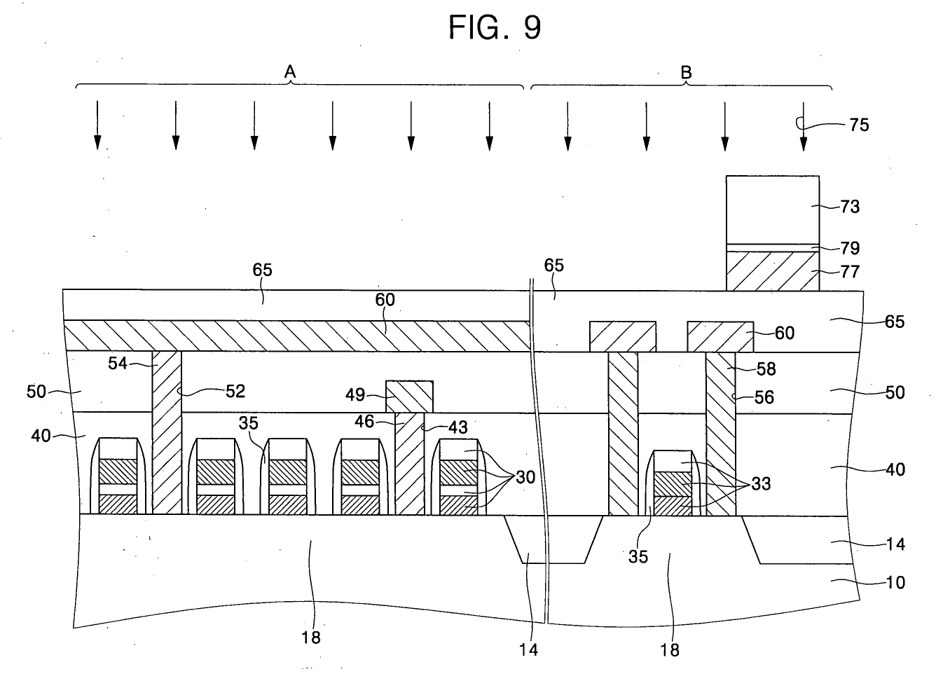

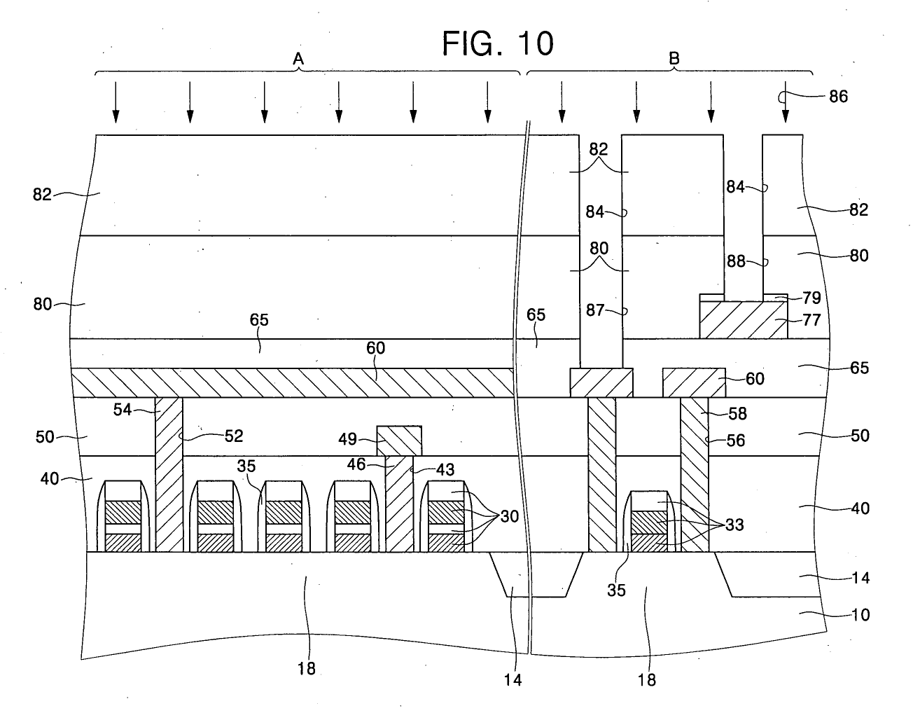

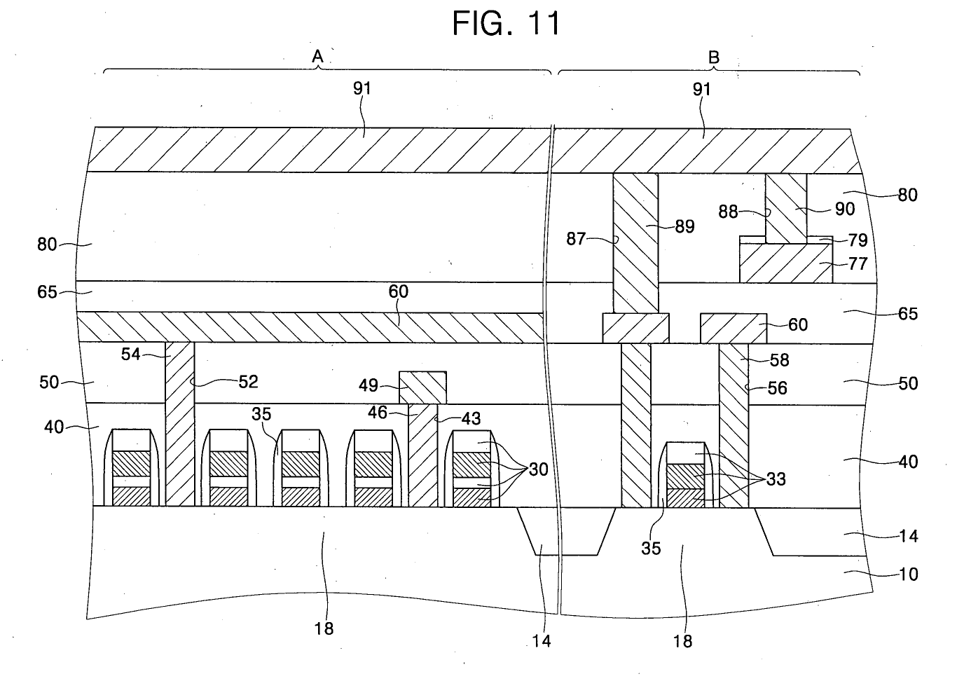

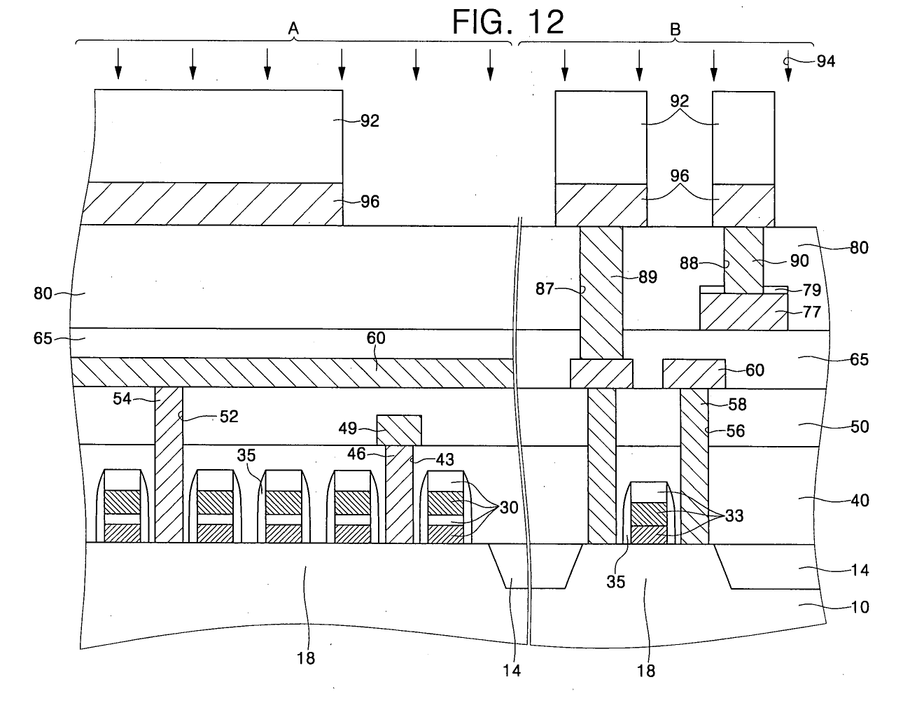

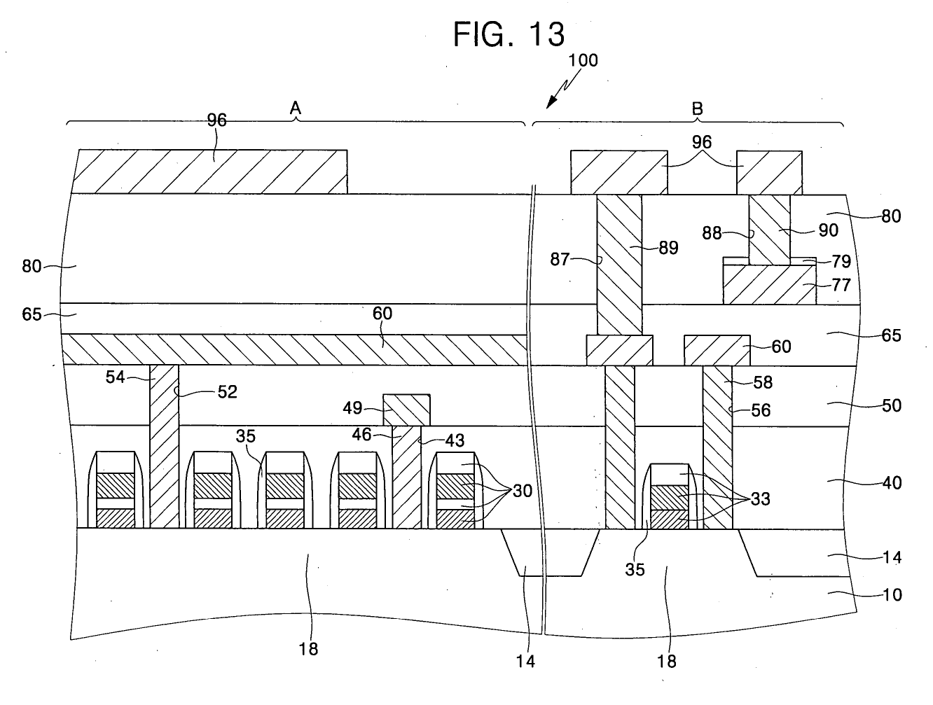

FIGS. 3 to 13 are sectional diagrams, taken along line I-I′ of FIG. 1, which illustrate a method of fabricating the flash memory of FIG. 1 according to some embodiments of the invention.

Referring to FIG. 1 and FIGS. 3 to 5, an isolation layer 14 is formed in the cell array region A and the peripheral circuit region B of the semiconductor substrate 10 to isolate the active regions 18. The isolation layer 14 is preferably formed using one or more insulating layers that have an etch rate that is different than the etch rate of the semiconductor substrate 10.

Gate patterns 30 are formed in the cell array region A, and a gate pattern 33 is formed in the peripheral circuit region B. In the cell array region A, the gate pattern 30 is formed using a floating gate 20, a dielectric layer 22, a control gate 24, and a gate capping layer pattern 26, which are sequentially stacked. In the peripheral circuit region B, the gate pattern 33 is formed using a floating gate 20, a control gate 24, and a gate capping layer pattern 26, which are sequentially stacked. The control gate 24 and the floating gate 20 are preferably formed using conductive polysilicon. The dielectric layer 22 is preferably formed using silicon oxide (SiO₂), silicon nitride (Si₃N₄), and silicon oxide, which are sequentially stacked.

Gate spacers 35 are formed on the sidewalls of each of the gate patterns 30, 33. The gate spacers 35 are preferably formed using silicon nitride or silicon oxide. A gate interlayer insulating layer 40 is formed on the semiconductor substrate 10 to cover the gate patterns 30, 33.

In the cell array region A, a source hole 43 is formed to penetrate the gate interlayer insulating layer 40. The source hole 43 is disposed in a region between the gate patterns 30 so as to expose the semiconductor substrate 10. A source landing pad 46 is formed to fill the source hole 43. The source landing pad 46 is preferably formed using tungsten (W).

Referring to FIGS. 1, 6 and 7, a source line 49 is formed on the gate interlayer insulating layer 40 to contact the source landing pad 46. The source line 49 is preferably composed of tungsten (W). A buried interlayer insulating layer 50 is formed on the gate interlayer insulating layer 40 to cover the source line 49. The buried interlayer insulating layer 50 is preferably formed of a material having the same etch rate as that of the gate interlayer insulating layer 40.

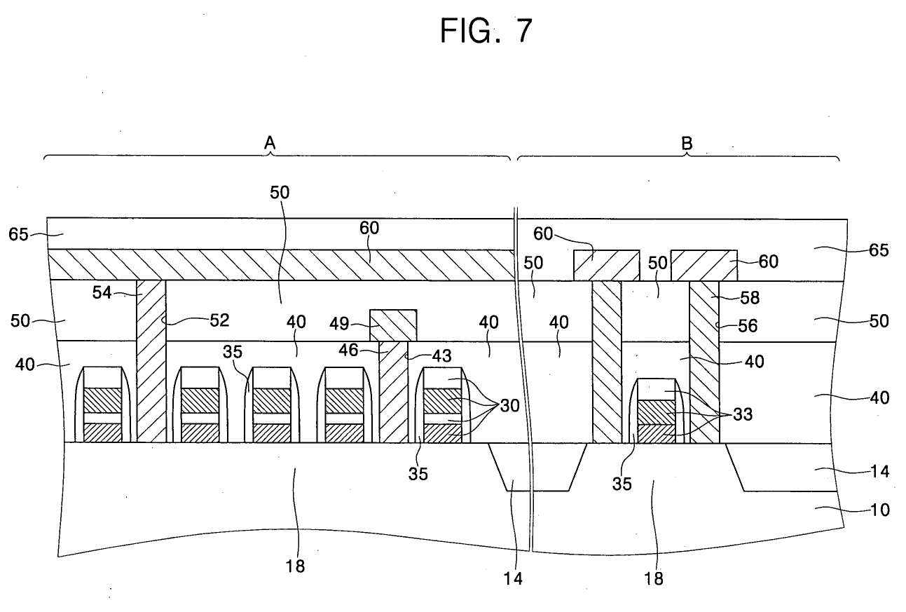

In the cell array region A, a drain hole 52 is formed to penetrate the buried interlayer insulating layer 50 and the gate interlayer insulating layer 40. The drain hole 52 is spaced apart from the source hole 43 and disposed between the gate patterns 30. A drain landing pad 54 is formed to fill the drain hole 52. The drain landing pad 54 is preferably formed using conductive polysilicon. As shown in FIG. 7, gate node holes 56 are formed to penetrate the buried interlayer insulating layer 50 and the gate interlayer insulating layer 40 in the peripheral circuit region B. The gate node holes 56 are disposed on both sides of the gate pattern 33 to expose the semiconductor substrate 10. Source and drain plugs 58 are formed to fill the gate node holes 56. The source and drain plugs 58 are preferably formed using tungsten (W).

Bit line patterns 60 are formed on the buried interlayer insulating layer 50 to contact the source and drain plugs 58 in the peripheral circuit region B and the drain landing pad 54 in the cell array region. The bit line patterns 60 are preferably formed using tungsten (W). In the cell array region A, the bit line pattern 60 is preferably formed perpendicular to the longitudinal direction of the gate patterns 30. A bit line interlayer insulating layer 65 is formed on the buried interlayer insulating layer 50 to cover the bit line patterns 60. The bit line interlayer insulating layer 65 is preferably formed using a material having the same etch rate as that of the buried interlayer insulating layer 50.

Referring to FIGS. 1, 8 and 9, a conductive layer 70 and an anti-reflection layer 71 are sequentially formed on the bit line interlayer insulating layer 65. The anti-reflection layer 71 minimizes the diffused reflection of a light used during a photolithography process. In alternative embodiments, the anti-reflection layer 71 may not be present. The conductive layer 70 is preferably formed using conductive polysilicon having a sheet resistance different than that of the floating gate 20 and the control gate 24 of the gate patterns 30, 33.

At least one photoresist pattern 73 is formed on the anti-reflection layer 71 in the peripheral circuit region B. The photoresist pattern 73 is preferably formed in parallel with the longitudinal direction of the bit line patterns 60, however, the photoresist pattern 73 may also be perpendicular to the longitudinal direction of the bit line patterns. An etch process 75 is sequentially performed on the anti-reflection layer 71 and the conductive layer 70 using the photoresist pattern 73 as an etch mask until the bit line interlayer insulating layer 65 is exposed. The etch process 75 forms a resistance pattern 77 and an anti-reflection layer pattern 79 that are sequentially stacked on the bit line interlayer insulating layer 65.

Similar to the illustrated embodiments, in some embodiments a photoresist pattern 73 may be formed in the cell array region A. The photoresist pattern 73 is preferably disposed in parallel with the longitudinal direction of the bit line patterns 60, crossing over the gate patterns 30. However, the photoresist pattern 73 may also be disposed perpendicular to the longitudinal direction of the bit line patterns 60, in a region between the gate patterns 30. An etch process 75 may be sequentially performed on the anti-reflection layer 71 and the conductive layer 70 using the photoresist pattern 73 as an etch mask until the bit line interlayer insulating layer 65 is exposed. Via the etch process 75, a resistance pattern 77 and a reflection layer pattern 79 may be sequentially stacked on the bit line interlayer insulating layer 65 in the cell array region A.

The resistance pattern 77 can singly show electrical characteristics of the conductive layer 70, unaffected by the thickness of the isolation layer 14. After the resistance pattern 77 is formed in the cell array region A or the peripheral circuit region B of the semiconductor substrate 10, the photoresist pattern 73 is removed from the semiconductor substrate 10.

Referring to FIGS. 1, 10 and 11, a planarized interlayer insulating layer 80 is formed on the bit line interlayer insulating layer 65 to cover the anti-reflection layer pattern 79 and the resistance pattern 77. The planarized interlayer insulating layer 80 is preferably formed using a material having the same etch rate as that of the buried interlayer insulating layer 65.

A photoresist layer 82 is formed on the planarized interlayer insulating layer 80. The photoresist layer 82 has openings 84 in the peripheral circuit region B that expose a region of the planarized interlayer insulating layer 80 above at least one of the bit line patterns 60 and the resistance pattern 77. An etch process 86 is performed on the planarized interlayer insulating layer 80 and the buried interlayer insulating layer 65 through the openings 84, using the photoresist layer 82 as an etch mask. The etch process 86 forms a bit line hole 87 and a connection hole 88 exposing at least one of the bit line patterns 60 and the resistance pattern 77, respectively. After the connection hole 88 and the bit line hole 87 are formed, the photoresist layer 82 is removed from the semiconductor substrate 10. Then, a connection landing pad 90 and a bit line landing pad 89, preferably composed of tungsten, are formed to fill the connection hole 88 and the bit line hole 87, respectively.

Similar to the illustrated embodiments, in some embodiments the photoresist layer 82 may be formed to have an opening 84 over the resistance pattern 77 in the cell array region A. An etch process 86 is performed on the planarized interlayer insulating layer 80 through the opening 84 using the photoresist layer 82 as an etch mask. The etch process 86 forms a connection hole 88 exposing the resistance pattern 77. After the connection hole 88 is formed, the photoresist layer 82 can be removed from the semiconductor substrate 10. A connection landing pad 90, preferably composed of tungsten, may be formed to fill the connection hole 88.

A metal layer 91 is formed on the planarized interlayer insulating layer 80 to cover the connection landing pad 90 and the bit line landing pad 89. The metal layer 91 preferably includes or is composed of aluminum (Al).

Referring to FIGS. 1, 12 and 13, photoresist patterns 92 are formed on the metal layer 91. An etch process 94 is performed on the metal layer 91 until the planarized interlayer insulating layer 80 is exposed. The etch process 94 forms metal interconnection lines 96 on the planarized interlayer insulating layer 80. After the metal interconnection lines 96 are formed, the photoresist patterns 92 are removed.

In the peripheral circuit region B, the metal interconnection lines 96 are formed to contact the bit line landing pad 89 and the connection landing pad 90. The metal interconnection lines 96 are preferably formed in parallel with the longitudinal direction of the bit line patterns 60 and the resistance pattern 77. The metal interconnection lines 96 may alternatively be formed perpendicular to the longitudinal direction of the bit line patterns 60 and the resistance pattern 77.

Similar to the illustrated embodiments, in some embodiments the metal interconnection lines 96 may be formed to contact a connection landing pad 90 in the cell array region A. The metal interconnection lines 96 are preferably disposed in parallel with the longitudinal direction of the bit line patterns 60, and formed to run across over the semiconductor substrate 10. Alternatively, the metal interconnection lines 96 may be formed perpendicular to the longitudinal direction of the bit line patterns 60.

Thus, according to some embodiments a flash memory 100 includes bit line patterns 60 and metal interconnection lines 96 in the cell array region A and the peripheral circuit region B.

As described above, a flash memory according to embodiments of the invention have at least one resistance pattern on the gate pattern that exhibits good electrical characteristics. Therefore, the flash memory minimizes the influence due to semiconductor fabrication processes so that it can be provided with a high production yield from a semiconductor substrate.

The invention may be practiced in many ways. What follows are exemplary, non-limiting descriptions of some embodiments of the invention.

According to some embodiments, a flash memory includes gate patterns disposed in first and second regions of a semiconductor substrate. Bit line patterns are disposed in the first and second regions of the semiconductor substrate. The bit line patterns are disposed on the gate patterns. At least one resistance pattern is disposed in the first region of the semiconductor substrate. The resistance pattern is disposed on the bit line patterns. Metal interconnection lines are disposed in the first and second regions of the semiconductor substrate. The metal interconnection lines are disposed on the resistance pattern. The metal interconnection lines and the bit line patterns in the first region of the semiconductor substrate are disposed to run across over the semiconductor substrate in substantially the same direction. At least one of the metal interconnection lines in the first region of the semiconductor substrate is disposed to contact with the resistance pattern.

According to some embodiments, a flash memory includes gate patterns disposed in first and second regions of a semiconductor substrate. Bit line patterns are disposed in the first and second regions of the semiconductor substrate. The bit line patterns are disposed on the gate patterns. At least one resistance pattern is disposed in the second region of the semiconductor substrate and disposed on the bit line patterns. Metal interconnection lines are disposed in the first and second regions of the semiconductor substrate. The metal interconnection lines are disposed on the resistance pattern. At least one of the metal interconnection lines in the second region of the semiconductor substrate is disposed to contact with the resistance pattern.

According to some embodiments, a method of fabricating a flash memory includes forming gate patterns disposed in first and second regions of a semiconductor substrate. Bit line patterns are formed on the gate patterns. The bit line patterns are formed in the first and second regions of the semiconductor substrate. A bit line interlayer insulating layer is formed to cover the bit line patterns. At least one resistance pattern is formed on the bit line interlayer insulating layer. The resistance pattern is formed in the first region of the semiconductor substrate. A planarized interlayer insulating layer is formed on the bit line interlayer insulating layer to cover the resistance pattern. Metal interconnection lines are formed on the planarized interlayer insulating layer. The metal interconnection lines are formed in the first and second regions of the semiconductor substrate. The metal interconnection lines and the bit line patterns are disposed to run across over the semiconductor substrate in substantially the same direction in the first region of the semiconductor substrate. At least one of the metal interconnection lines is formed to contact with the resistance pattern.

According to some embodiments, a method of fabricating a flash memory includes forming gate patterns disposed in first and second regions of a semiconductor substrate. Bit line patterns are formed on the gate patterns. The bit line patterns are formed in the first and second regions of the semiconductor substrate. A bit line interlayer insulating layer is formed to cover the bit line patterns. At least one resistance pattern is formed on the bit line interlayer insulating layer. The resistance pattern is formed in the second region of the semiconductor substrate. A planarized interlayer insulating layer is formed on the bit line interlayer insulating layer to cover the resistance pattern. Metal interconnection lines are formed on the planarized interlayer insulating layer. The metal interconnection lines are formed in the first and second regions of the semiconductor substrate. At least one of the metal interconnection lines is disposed to contact the resistance pattern.

Specific exemplary embodiments of the invention were disclosed above for the purpose of illustrating inventive principles common to one or more of the embodiments, not for purposes of limitation. Accordingly, it will be understood by those of skill in the art that various changes may be made to the form and details of the exemplary embodiments described above without departing from the inventive principles that are set forth in the attached claims.

1. A flash memory comprising:
gate patterns disposed in a first region and a second region of a semiconductor substrate;
bit line patterns disposed in the first region and the second region, the bit line patterns arranged over the gate patterns;
at least one resistance pattern disposed in the first region, the at least one resistance pattern arranged over one of the bit line patterns; and
interconnection lines disposed in the first region and the second region, one of the interconnection lines in electrical contact with the resistance pattern and arranged over the resistance pattern, the interconnection lines and the bit line patterns in the first region arranged to cross over the semiconductor substrate in substantially the same direction.

2. The flash memory of claim 1, the resistance pattern arranged parallel to a longitudinal direction of the bit line patterns in the first region and arranged to cross over the gate patterns.

3. The flash memory of claim 1, the resistance pattern arranged perpendicular to a longitudinal direction of the bit line patterns in the first region and arranged to cross over the gate patterns.

4. The flash memory of claim 1, the first region comprising a cell array region and the second region comprising a peripheral circuit region.

5. The flash memory of claim 1, further comprising an isolation layer disposed in the first region and the second region to define and isolate active regions, the resistance pattern aligned with the isolation layer such that a vertical line passing through the resistance pattern also passes through the isolation layer.

6. The flash memory of claim 1, further comprising an isolation layer disposed in the first region and the second region to define and isolate active regions, the resistance pattern crossing over the active regions.

7. A semiconductor device comprising:
gate patterns disposed in a first region and a second region of a semiconductor substrate;
bit line patterns disposed in the first and second regions and disposed on the gate patterns;
at least one resistance pattern disposed in the second region and disposed on one of the bit line patterns; and
interconnection lines disposed in the first region and in the second region, one of the interconnection lines arranged on the at least one resistance pattern and in electrical contact with the resistance pattern.

8. The device of claim 7, the resistance pattern arranged parallel to a longitudinal direction of the bit line patterns and the interconnection lines in the second region.

9. The device of claim 7, the resistance pattern arranged perpendicular to a longitudinal direction of the bit line patterns and the interconnection lines in the second region.

10. The device of claim 7, the first region comprising a cell array region, the second region comprising a peripheral circuit region.

11. The device of claim 7, further comprising an isolation layer disposed in the first region and the second region to define and isolate active regions, the resistance pattern aligned with the isolation layer such that a vertical line passing through the resistance pattern also passes through the isolation layer.

12. The device of claim 7, further comprising an isolation layer disposed in the first region and the second region to define and isolate active regions, the resistance pattern crossing over the active regions.

13. A method of fabricating a flash memory comprising:
forming gate patterns that are disposed in a first region and in a second region of a semiconductor substrate;
forming bit line patterns on the gate patterns;
covering the bit line patterns with a bit line interlayer insulating layer;
forming at least one resistance pattern on the bit line interlayer insulating layer in the first region;
covering the resistance pattern and the bit line interlayer insulating layer with a planarized interlayer insulating layer; and
forming interconnection lines on the planarized interlayer insulating layer in the first and second regions of the semiconductor substrate, the interconnection lines and the bit line patterns crossing over the semiconductor substrate in the first region of the semiconductor substrate in substantially the same direction, one of the interconnection lines in electrical contact with the at least one resistance pattern.

14. The method of claim 13, wherein forming the interconnection lines comprises:
forming a metal layer on the planarized interlayer insulating layer;
forming photoresist patterns on the metal layer; and
etching the metal layer using the photoresist patterns as an etch mask to expose the planarized interlayer insulating layer.

15. The method of claim 13, wherein forming interconnection lines comprises forming a photoresist layer on the planarized interlayer insulating layer, the photoresist layer having an opening in the first region that is over the resistance pattern.

16. The method of claim 15, further comprising:
etching the planarized interlayer insulating layer through the opening using the photoresist layer as an etch mask to form a connection hole that exposes the resistance pattern; and
filling the connection hole with a connection landing pad, the connection landing pad contacting the one of the interconnection lines.

17. The method of claim 13, the planarized interlayer insulating layer and the bit line interlayer insulating layer having the same etch rate.

18. The method of claim 13, wherein forming the resistance pattern comprises:
forming a conductive layer and a photoresist pattern on the bit line interlayer insulating layer, the photoresist pattern parallel to a longitudinal direction of the bit line patterns in the first region, the photoresist pattern disposed to cross over the gate patterns; and
etching the conductive layer using the photoresist pattern as an etch mask to expose the bit line interlayer insulating layer.

19. The method of claim 13, wherein the forming the resistance pattern comprises:
forming a conductive layer and a photoresist pattern on the bit line interlayer insulating layer, the photoresist pattern perpendicular to a longitudinal direction of the bit line patterns in the first region, the photoresist pattern disposed between the gate patterns; and
etching the conductive layer using the photoresist pattern as an etch mask to expose the bit line interlayer insulating layer.

20. The method of claim 13, the first region comprising a cell array region, the second region comprising a peripheral circuit region.

21. The method of claim 13, further comprising defining and isolating active regions in the first region and the second region using an isolation layer, the isolation layer aligned with the resistance pattern such that a vertical line passing through the resistance pattern also passes through the isolation layer.

22. The method of claim 13, wherein forming the resistance pattern comprises forming the resistance pattern to cross over active regions that are defined and isolated by an isolation layer disposed in the first region and the second region.

23. A method of fabricating a semiconductor device comprising:
forming gate patterns that are disposed in a first region and a second region of a semiconductor substrate;
forming bit line patterns on the gate patterns in the first region and the second region;
covering the bit line patterns with a bit line interlayer insulation layer;
forming at least one resistance pattern on the bit line interlayer insulating layer in the second region;
covering the bit line interlayer insulating layer and the resistance pattern with a planarized interlayer insulating layer; and
electrically connecting a interconnection line to the at least one resistance pattern, the interconnection line one of a plurality of interconnection lines formed on the planarized interlayer insulating layer in the first region and in the second region.

24. The method of claim 23, wherein electrically connecting the interconnection line to the resistance pattern comprises:
forming a metal layer on the planarized interlayer insulating layer;
forming photoresist patterns on the metal layer; and
etching the metal layer using the photoresist patterns as an etch mask to expose the planarized interlayer insulating layer.

25. The method of claim 23, wherein electrically connecting the interconnection line to the resistance pattern comprises forming a photoresist layer on the planarized interlayer insulating layer, the photoresist layer having openings over one of the bit line patterns and over the resistance pattern in the second region of the semiconductor substrate.

26. The method of claim 25, further comprising:
using the photoresist layer as an etch mask, etching the planarized interlayer insulating layer and the bit line interlayer insulating layer through the openings to form a bit line hole exposing the one of the bit line patterns and a connection hole exposing the resistance pattern;
filling the connection hole with a connection landing pad; and
filling the bit line hole with a bit line landing pad.

27. The method of claim 23, the planarized interlayer insulating layer and the bit line interlayer insulating layer having substantially the same etch rate.

28. The method according of claim 23, wherein forming the resistance pattern comprises:
forming a conductive layer and a photoresist pattern on the bit line interlayer insulating layer, the photoresist pattern parallel to a longitudinal direction of the bit line patterns and the interconnection lines in the second region; and
etching the conductive layer using the photoresist pattern as an etch mask to expose the bit line interlayer insulating layer.

29. The method of claim 23, wherein forming the resistance pattern comprises:
forming a conductive layer and a photoresist pattern on the bit line interlayer insulating layer, the photoresist pattern perpendicular to a longitudinal direction of the bit line pattern and the interconnection lines in the second region; and
etching the conductive layer using the photoresist pattern as an etch mask to expose the bit line interlayer insulating layer.

30. The method of claim 23, further comprising defining and isolating active regions in the first region and the second region using an isolation layer, the isolation layer aligned with the resistance pattern such that a vertical line passing through the resistance pattern also passes through the isolation layer.

31. The method of claim 23, wherein forming the resistance pattern comprises forming the resistance pattern to cross over active regions that are defined and isolated by an isolation layer disposed in the first region and the second region.
